(19) United States
(12) Patent Application Publication
(10) Pub. No.: US 2012/0318347 A1
(43) Pub. Date: Dec. 20, 2012

(54) ANTIREFLECTION COATING AS WELL AS SOLAR CELL AND SOLAR MODULE THEREWITH

(75) Inventors: Matthias Junghänel, Leipzig (DE); Martin Schädel, Halle (Saale) (DE)

(73) Assignee: Q-CELLS SE, BITTERFELD-WOLFEN/ OT THALHEIM (DE)

(21) Appl. No.: 13/513,705

(22) PCT Filed: May 26, 2010
(86) PCT No.: PCT/EP10/57275

§ 371 Date: Aug. 6, 2012

(30) Foreign Application Priority Data
Dec. 4, 2009 (DE) 102009056594.9

(51) Int. Cl. B32B 9/04; H01L 31/0216

(52) U.S. Cl. 136/256; 428/446; 428/336; 136/246

(57) ABSTRACT

An antireflection coating for a solar cell includes at least a first SiNₓ layer with a high refractive index and a second SiNₓ layer with a lower refractive index. An improved light coupling and a better passivation of solar cells and a more homogeneous and darker color impression may be achieved also in the laminated in solar module, while at the same time being insensitive to typical process variations.

### CROSS REFERENCE TO RELATED APPLICATIONS

This application is a 371 National stage of PCT International Application No. PCT/EP2010/057275 filed on May 26, 2010, and published in English on Jun. 9, 2011 as WO 2011/066999 A2, which claims priority to German Application No. 10 2009 056 594.9 filed on Dec. 4, 2009, the entire disclosures of which are incorporated herein by reference.

### DESCRIPTION

The present invention relates to an antireflection coating according to the preamble of claim 1, a solar cell according to the preamble of claim 7, as well as a solar module according to the preamble of claim 9.

Solar cells usually consist of a p-n structure, which is built on an electrically conducting semiconductor substrate, wherein a conductive layer is placed on the semiconductor substrate and a p-n junction is at the interface between the substrate and the conductive layer. In order to couple as much light into the solar cell as possible, an antireflection coating is placed on the first conductive layer in order to avoid the loss of light due to reflection.

Such an antireflection coating consist in silicon-based solar cells in general of an about 75 nm thick SiNₓ layer with a refractive index of n=2.05. Due to interference, the reflection is reduced by this antireflection coating, wherein minimum reflection is at 4*n*d=approximately 620 nm. By selecting this layer thickness, a maximum light coupling in the spectral region relevant for the sun spectrum is achieved, and the layer thickness causes the solar cells to appear blue. The refractive index is wavelength dependent and is specified in the present application in general for λ=632 nm.

Due to the manufacturing process of such antireflection coatings in a PECVD process (plasma enhanced chemical vapor deposition process), hydrogen is incorporated during the deposition of the antireflection coating, i.e. the SiNₓ layer is hydrogenised, which is illustrated by the expression SiNₓ:H layer. This hydrogen contained in the layer passivates recombination centers at the SiNₓ/Si interface and in the volume of the silicon substrate. Therefore, the efficiency of such solar cells is affected positively.

However, this technical solution has numerous disadvantages. For example, single layer antireflection coatings can suppress reflections practically completely only for a certain wavelength. Therefore, for a usual quantum efficiency of a microcrystalline solar cell, the reflection losses in the relevant spectral region add to approximately 3 mAcm⁻².

Furthermore, the color impression of the silicon-based solar cell depends strongly on the layer thickness of the SiNₓ layer. Due to variations of the layer thickness across the wafer (substrate) or in between two wafers, as are common in industrially utilized PECVD reactors, this color impression varies, however, typically from light blue to violet. Therefore, the quality appearance of the solar cell or of a solar cell module is compromised, because it is perceived as obviously not homogeneous.

Furthermore, as is known, the passivation of the SiNₓ/Si interface or the silicon volume in the substrate is enhanced with rising refractive index of the SiNₓ layer. However, the absorption arises simultaneously with rising refractive index, which is why highly refractive SiNₓ cannot be utilized for such singular layer antireflection coatings, since otherwise the yield of light through absorption will be reduced.

While the effect of the antireflection coating regarding its light coupling and passivation in single layer systems can in principle not be enhanced, color deviation can be reacted to by measuring the color of the solar cell after the SiNₓ coating, and adjusting the deposition time for SiNₓ in case of color deviations.

Such a conventional solar cell with a single layer SiNₓ coating has on silicon wafers, which were used in the experiments presented here, usually a short circuit current I_{SC} of approximately 33.2 mAcm⁻², the open circuit voltage is approximately 604.5 mV, and the filling factor, which as quotient of the maximum power of the solar cell and the products of open circuits voltage and short circuit current reveals something about the quantity of the solar cell, is about 78%. The efficiency is typically 15.6%.

These values are, however, not exclusively relevant, since in practice solar cells are operated mostly in solar modules, where these solar cells are laminated in, wherein during laminating-in, a stack consisting of polymer foil (typically EVA) and a glass plate is glued on the light coupling side of the solar cell and the entire module is encapsulated airtight. The above-mentioned values now change in such solar modules, since here additional interfaces are present, which change the light coupling. Furthermore, mostly also the electric conditions are changed, so that the efficiency of the solar cell in the solar module is changed.

One possibility for enhancing the light coupling consists of designing the antireflection coating as a two layer system, with a silicon oxynitride layer (SiNₓO_{y}) oriented in the direction towards the interface to air, and a SiNₓ layer applied thereon, which is oriented in the direction towards the p-n junction. With this two layer system, it is possible to raise the short-circuit current for non-laminated solar cells by approximately 2% compared to that of solar cells with a single antireflection coating. The short-circuit current is, however, improved by only 0.5% for the laminated-in solar cell in a solar module.

A further approach for improving the antireflection coating is described in WO 2008/062934 A1, wherein also a two layer system is utilized with a first layer of SiNₓ, and a second layer, which is oriented in the direction toward the interface to air and consists of an insulating material containing silicon. This way, with a top insulating layer of silicon oxynitride, the short-circuit current could be improved to approximately 33.3 mA and the open circuit voltage to 619.9 mV, with a filling factor of 78.2%. However, no details are given for laminated-in solar cells.

It is therefore the object of the present invention, to specify an antireflection coating that improves significantly the relevant parameters of a solar cell both in an exposed and in a laminated-in condition. In particular, solar cells produced therewith are to have a significantly lower sensitivity of their color impression against layer thickness variations, and they are to obtain an improved passivation. Furthermore, it is desirable that the antireflection coating according to the invention can be produced in a simple and cost-effective manner. Besides this antireflection coating, also solar cells and solar cell modules are to be provided.

This object is solved with an antireflection coating according to claim 1, a solar cell according to claim 7 and a solar module according to claim 9. Advantageous embodiments are subject of the dependent claims.

The antireflection coating according to the invention, in particular for silicon-based, preferably multi- or monocrystalline solar cells, solar modules and the like, comprises a layer of SiNₓ, and the antireflection coating comprises at least a first SiNₓ layer with a high refractive index and a second SiNₓ layer with a lower refractive index, wherein the first and the second SiNₓ layer are in particular SiNₓ:H layers.

Due to the antireflection coating according to the invention, which consists of at least two SiNₓ layers, on the one hand an improved light coupling is achieved, because thereby not only a narrow reflection minimum, but a wide reflection depression is provided. On the other hand, the color impression of a solar cell manufactured therewith is altered considerably into the very dark blue, thereby accomplishing that possible layer thickness variations have barely an effect on the optical impression, because the eye can distinguish different shades of dark blue more poorly than for example a light blue from a violet.

Advantageously, it may be provided for the antireflection coating to comprise at least a SiNₓO_{y} layer, wherein the SiNₓO_{y} layer is preferably a SiNₓO_{y}:H layer, wherein in particular the SiNₓO_{y} layer has a refractive index that is lower than the refractive index of the second SiNₓ layer, wherein the second SiNₓ layer is preferably placed between the first SiNₓ layer and the SiNₓO_{y} layer. Due to the additional providing with a silicon oxynitride layer, the light coupling can be enhanced further, and the representation of a pure black tone as an optical color impression is also possible. With this black appearance, a significant sales advantage can be achieved compared to blue solar modules, because such black solar modules can sell better for reasons of fashion, and also because of the possibility of combining them with colors, with which blue solar modules cannot be combined due to esthetic reasons.

In an advantageous embodiment, the refractive index difference between the first and the second SiNₓ layer and/or between the second SiNₓ layer and the SiNₓO_{y} layer is at least 0.2. Due to providing such a refractive index difference, a high efficiency of the antireflection coating is ensured.

In an especially preferred embodiment, the antireflection coating is characterized by that the refractive index of the first SiNₓ layer is 2.1 to 2.8, preferably 2.25 to 2.6, and/or the refractive index of the second SiNₓ layer is 1.8 to 2.3, preferably 1.9 to 2.15, and/or the refractive index of the SiNₓO_{y} layer is 1.45 to 1.9, preferably 1.45 to 1.7, and/or that the thickness of the first SiNₓ layer is 10 nm to 70 nm, preferably 20 nm to 55 nm, and/or the thickness of the second SiNₓ layer is 5 nm to 60 nm, preferably 10 nm to 50 nm, and/or the thickness of the SiNₓO_{y} layer is ≧20 nm, preferably ≧30 nm.

In the region of these corridor values for refractive index and layer thickness, the antireflection coating has a large light coupling effect, and furthermore a large passivation effect is provided.

Preferably, it may be provided that between the first and the second SiNₓ layer, a third SiNₓ layer is provided, whose refractive index has the form of a gradient, wherein the largest refractive index is smaller than or equal the refractive index of the first SiNₓ layer and the smallest refractive index is larger than or equal the refractive index of the second SiNₓ layer. In this case, it may be preferred that the largest refractive index of the third SiNₓ layer is at most 2.4, preferably at most 2.3, in particular 2.25, and the smallest refractive index is at least 1.9, preferably at least 1.95, in particular at least 1.97, and/or that the thickness of the third SiNₓ layer is 5 nm to 70 nm, preferably 10 nm to 50 nm. Hereby, the light coupling can be further optimized.

Independent protection is claimed for a solar cell, in particular a silicon-based, preferably multi- or monocrystalline solar cell, with at least one p-n junction, whereby the solar cell comprises the antireflection coating according to the invention, wherein preferably the first SiNₓ layer is oriented in a direction toward the p-n junction, and the second SiNₓ layer in a direction toward an interface to air.

In a particularly preferred embodiment, the solar cell according to the invention is characterized by that the refractive index of the first SiNₓ layer is 2.45, the refractive index of the second SiNₓ layer is 2, and the refractive index of the SiNₓO_{y} layer is 1.50, wherein the thickness of the first SiNₓ layer is 45 nm, the thickness of the second SiNₓ layer is 15 nm, and the thickness of the SiNₓO_{y} layer is 85 nm. Such a solar cell is characterized, depending on the utilized texturing, by a dark blue to black color impression, very good passivation and large light coupling.

Alternatively, the solar cell according to the invention is characterized by that the refractive index of the first SiNₓ layer is 2.25, the refractive index of the second SiNₓ layer is 1.97, and the refractive index of the third SiNₓ layer is between 2.25 and 1.97, wherein the thickness of the first SiNₓ layer is 15 nm, the thickness of the second SiNₓ layer is 30 nm, and the thickness of the third SiNₓ layer is 38 nm. In this case, no additional SiNₓO_{y} layer is provided, although this is of course also possible. Such a solar cell is characterized by a dark blue color impression, very good passivation and large light coupling.

Furthermore, independent protection is claimed for a solar module made of at least one laminated-in solar cell, in particular a silicon-based, preferably multicrystalline solar cell, wherein the solar cell comprises at least one p-n junction, wherein the solar cell is a solar cell according to the invention.

In a particularly preferred embodiment, the solar module is characterized by that the refractive index of the first SiNₓ layer is 2.45, the refractive index of the second SiNₓ layer is 2, and the refractive index of the SiNₓO_{y} layer is 1.6, wherein the thickness of the first SiNₓ layer is 43 nm, the thickness of the second SiNₓ layer is 36 nm, and the thickness of the SiNₓO_{y} layer is 60 nm. Such a solar module is characterized by a black color impression, a high light yield and a very good passivation. The values were slightly corrected compared to the solar cell of the invention, in order to carry out an adaptation to the changed conditions due to the laminating-in.

The characteristics of the present invention as well as further advantages will become clear in the following with the help of the description of preferred embodiments in connection with the drawing. Herein:

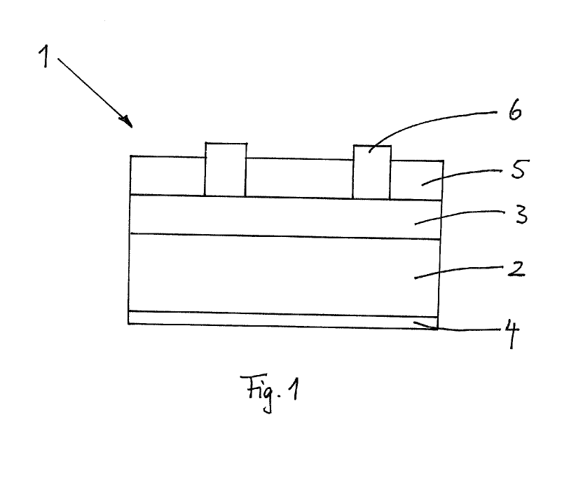

FIG. 1 shows a solar cell according to the invention,

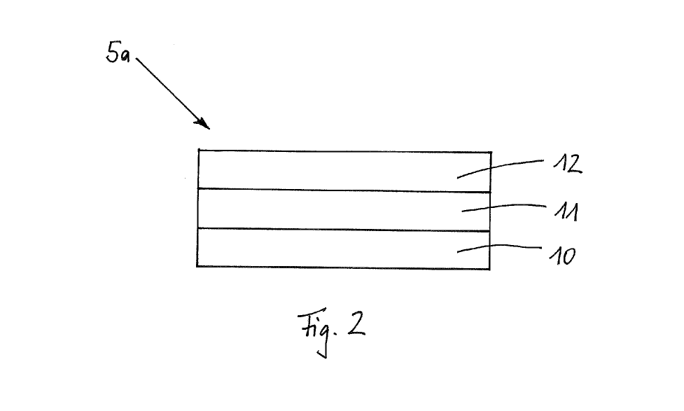

FIG. 2 shows an antireflection coating according to the invention in a first embodiment,

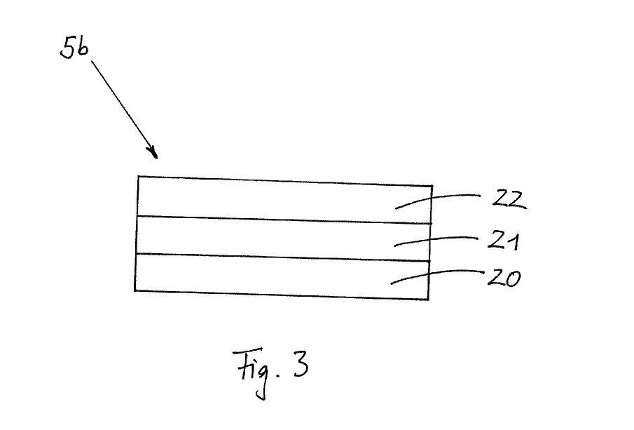

FIG. 3 shows an antireflection coating according to the invention in a second embodiment,

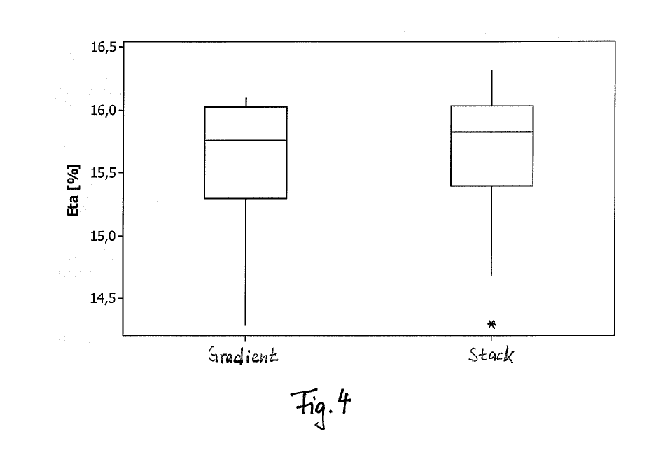

FIG. 4 shows a comparison of efficiencies for solar cells according to the invention having antireflection coatings according to FIG. 2 and FIG. 3,

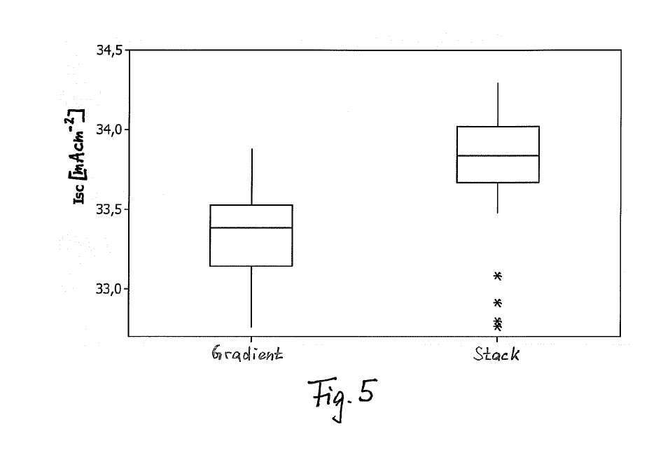

FIG. 5 shows the short circuit current of solar cells according to the invention having antireflection coatings according to FIG. 2 and FIG. 3,

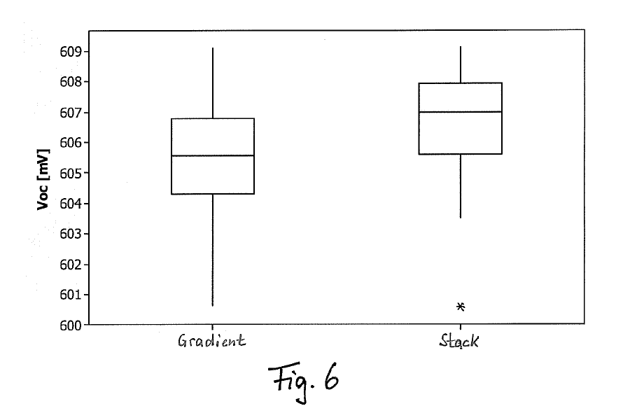

FIG. 6 shows the open circuit voltage of solar cells according to the invention having antireflection coatings according to FIG. 2 and FIG. 3,

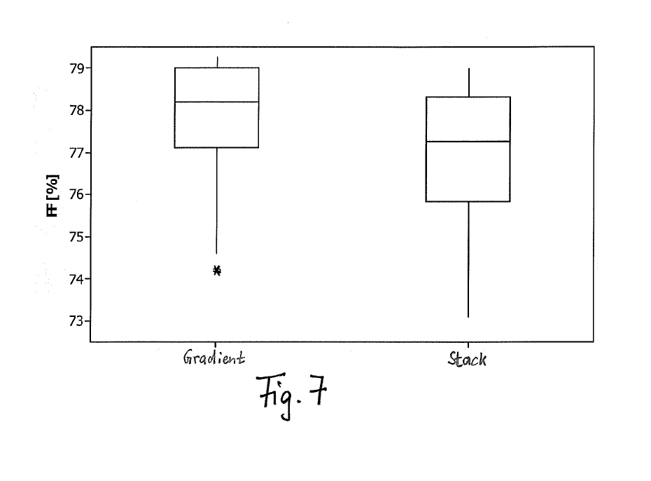

FIG. 7 shows the filling factor of solar cells having antireflection coatings according to FIG. 2 and FIG. 3, and

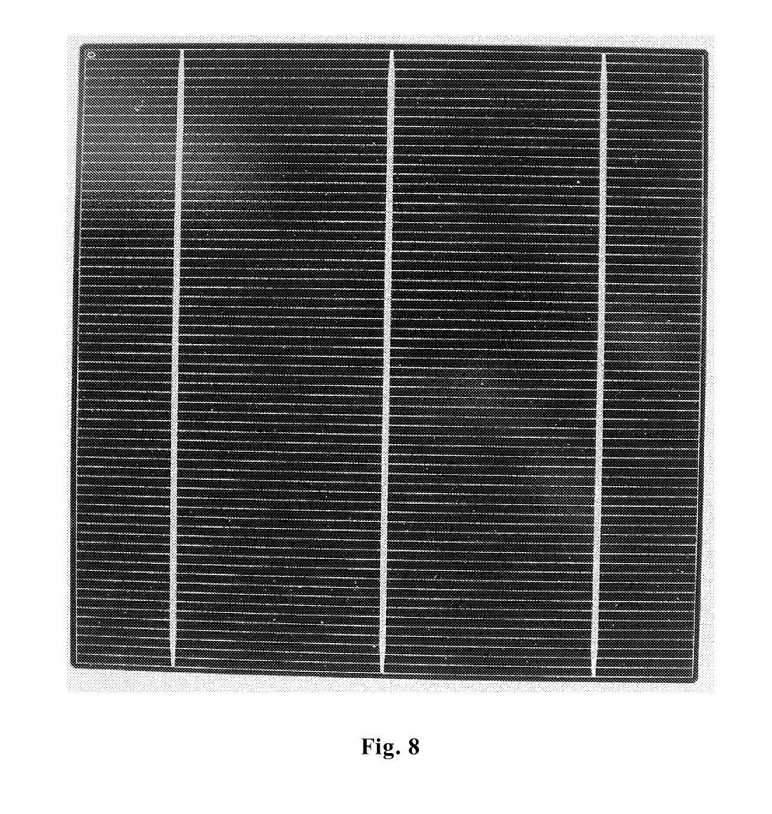

FIG. 8 shows an appearance of a laminated-in solar cell according to the invention having an antireflection coating according to FIG. 2.

In FIG. 1 the solar cell 1 according to the invention is depicted purely schematically in cross section, comprising an electrically conductible, semiconducting silicon substrate 2, an electrically conductible silicon layer 3, a back side electrode 4 out of aluminum, an antireflection coating 5, and a front side electrode 6 out of silver. At the interface between the substrate 3 and the silicon layer 3, a p-n junction is formed.

The antireflection coatings 5 used in the solar cell 1 according to the invention may now be designed according to the invention for example according to preferred embodiments shown in FIG. 2 and FIG. 3. FIG. 2 and FIG. 3 show hereby, purely schematically in cross section, antireflection coatings 5a, 5b, whereby the antireflection coating 5a is built according to a first preferred embodiment shown in FIG. 2 as a three layer system, consisting of a first SiNₓ:H layer 10 having a high refractive index, a second SiNₓ:H layer 11 having a low refractive index, and a SiNₓO_{y}:H layer 12 having an even lower refractive index. Namely, the first SiNₓ:H layer 10 has a refractive index of 2.45 and a layer thickness of 43 nm. The second SiNₓ:H layer 11 has a layer thickness of 36 nm and a refractive index of 2, and the SiNₓO_{y}:H layer 12 has a refractive index of 1.6 and a thickness of 60 nm.

The antireflection coating 5b according to FIG. 3 is also a three layer system, however, without an additional SiNₓO_{y} layer, consisting of a first SiNₓ:H layer 20 having a refractive index of 2.25 and a thickness of 15 nm, a thereon arranged third SiNₓ:H layer 21 having a thickness of 38 nm and a continuous refractive index progression beginning from 2.25 and ending at 1.97, and a thereon arranged second SiNₓ:H layer 22 having a refractive index of 1.97 and a layer thickness of 30 nm.

In FIGS. 4 to 7, individual parameters of laminated solar cells 1 not according to the invention are compared, wherein the antireflection coating 5 is in one case specified according to antireflection coating 5a (indicated as “Stack” in the graphics) and 5b (indicated as “Gradient” in the graphics). The Graphics in the FIGS. 4 to 7 hereby each show so called box plots, each containing 80 data points. The data points hereby have each been obtained on microcrystalline (mc) solar cells, which have been obtained from wafers, which were arranged adjacent to each other in the ingot used for the production.

It shows that the values efficiency Eta, short circuit current I_{sc}, open circuit voltage V_{OC}, and filling factor FF for the manufactured solar cells 1 are in part notably better than for usual solar cells having antireflection coatings consisting of only one SiNₓ:H layer. In detail, with the antireflection coating 5b according to FIG. 3, an improvement of the open circuit voltage of 1 mV and an improvement of the short circuit current of 0.2 mAcm⁻² can be obtained. With the antireflection coating 5a according to FIG. 2, which contains no gradient layer 21, the passivation may be further improved and thereby the open circuit voltage raised by further 1.5 mV. In addition, even more light may be coupled in and thereby the short circuit current improved by further 0.4 mAcm⁻².

While in improved antireflection coatings known to date the larger light coupling only existed before the laminating-in, the antireflection coatings 5a, 5b according to the invention cause the light coupling to be even notably larger also after the lamination, as could be predicted by simulation as well as confirmed through appropriate experiments.

In detail, the efficiency according to FIG. 4 is on average about 15.75% for the antireflection coating 5b, and about 15.8% for the antireflection coating 5a. The short circuit current according to FIG. 5 is on average about 33.4 mAcm⁻² for the antireflection coating 5b, and about 33.8 mAcm⁻² for the antireflection coating 5a. The open circuit voltage is on average approximately 605.5 mV for the antireflection coating 5b, and approximately 607 mV for the antireflection coating 5a. The filling factor is on average approximately 78.2% for the antireflection coating 5b, and approximately 77.2% for the antireflection coating 5a.

The worse filling factor for the antireflection coating 5a according to FIG. 7 has no fundamental cause, but is instead due to the fact that the contacting process for creating the front side electrode 6 on the solar cell 1 had been optimized in view of the process parameters to the antireflection coating 5b according to FIG. 3. Therefore, it is assumed that this processing is not optimal for an antireflection coating 5a according to FIG. 2, and that inadequate contacting cause resistance losses, since the contacting process takes place by the electrode burning through the antireflection coating 5, and layer thickness and materials are in this respect essential influencing factors. However, in principle, the filling factor for the antireflection coating 5a should be improved further and in particular be possible to be held higher compared to the antireflection coating 5b.

Finally, in FIG. 8 is shown a photographic image of a laminated-in solar cell 1 according to the invention, which has as an antireflection coating 5 a three layer system 5a according to FIG. 2. From the image it is clearly recognizable that a very uniform color impression is created, which is completely black, as shown in the original color image underlying the image. The color impression partially appearing slightly lighter in the top left corner, is attributed to a reflection during photographing, and therefore has no cause in a layer deviation. Although the laminated-in solar cell 1 according to FIG. 8 has also slightly deviating layer thicknesses, it is accomplished with the antireflection coating 5a according to the invention, that the color impression is nevertheless very constant.

Due to the present description, it has become clear that with the present invention the properties of antireflection coatings and especially of solar cells, in particular microcrystalline silicon-based solar cells, can be improved in a synergetic manner, whereby a better light coupling, a better passivation, and a more homogeneous and darker color impression in the laminated-in module is achieved, being at the same time insensitive against typical process variations.

Thereby it has been surprisingly recognized by the inventors that despite the highly refractive SiNₓ:H layers 10, 20 with a refractive index of approximately 2.4, it is possible to develop an antireflection coating 5a, 5b that due to substantial reflection reduction is able to couple altogether more light into the solar cell 1 according to the invention. Due to the antireflection coating 5a, 5b according to the invention, it is for the first time possible to obtain an efficiency advantage against standard single layer antireflection coatings for solar modules built with the solar cell 1 according to the invention, due to better light coupling.

1. Antireflection coating for a silicon-based, multi- or monocrystalline solar cells, solar modules, comprising a layer of SiNₓ, wherein the antireflection coating comprises it least a first SiNₓ layer with a high refractive index and a second SiNₓ layer with a lower refractive index, wherein the first and the second SiNₓ layer are SiNₓ:H layers.

2. The antireflection coating of claim 1, further comprising at least one SiNₓO_{y} layer, wherein the SiNₓO_{y} layer is a SiNₓO_{y}:H layer, wherein the SiNₓO_{y} layer has a refractive index that is lower than the refractive index of the second SiNₓ layer, wherein the second SiNₓ layer is placed between the first SiNₓ layer and the SiNₓO_{y} layer.

3. The antireflection coating of claim 1, wherein at least one of the refractive index difference between the first and the second SiNₓ layer and between the second SiNₓ layer and the SiNₓO_{y} layer is at least 0.2.

4. The antireflection coating of claim 1, wherein at least one of the refractive index of the first SiNₓ layer is 2.1 to 2.8, the refractive index of the second SiNₓ layer is 1.8 to 2.3, the refractive index of the SiNₓO_{y} layer is 1.45 to 1.9, the thickness of the first SiNₓ layer is 10 nm to 70 nm, the thickness of the second SiNₓ layer is 5 nm to 60 nm, and the thickness of the SiNₓO_{y} layer is greater than or equal to 20 nm.

5. The antireflection coating of claim 1, wherein between the first and the second SiNₓ layer is provided a third SiNₓ layer, whose refractive index has the form of a gradient, wherein the largest refractive index is smaller than or equal the refractive index of the first SiNₓ layer and the smallest refractive index is larger than or equal the refractive index of the second SiNₓ layer.

6. The antireflection coating of claim 5, wherein at least one of the largest refractive index of the third SiNₓ layer is at most 2.4, the smallest refractive index is at least 1.9, and the thickness of the third SiNₓ layer is 5 nm to 70 nm.

7. A multi- or monocrystalline solar cell, with at least one p-n junction, wherein the solar cell comprises an antireflection coating according to claim 1, wherein the first SiNₓ layer is oriented in a direction toward the p-n junction and the second SiNₓ layer in a direction toward an interface to air.

8. The solar cell of claim 7, wherein the refractive index of the first SiNₓ layer is 2.45, the refractive index of the second SiNₓ layer is 2, and the refractive index of the SiNₓO_{y} layer is 1.50, wherein the thickness of the first SiNₓ layer is 45 nm, the thickness of the second SiNₓ layer is 15 nm, and the thickness of the SiNₓO_{y} layer is 85 nm, or refractive index of the first SiNₓ layer is 2.25, the refractive index of the second SiNₓ layer is 1.97, and the refractive index of the third SiNₓ layer is between 2.25 and 1.97, wherein the thickness of the first SiNₓ layer is 15 nm, the thickness of the second SiNₓ layer is 30 nm, and the thickness of the third SiNₓ layer is 38 nm.

9. A solar module made of at least one silicon-based, preferably multi- or monocrystalline solar cell, wherein the solar cell comprises at least one p-n junction, wherein the solar cell is a solar cell according to claim 7.

10. The solar module of claim 9, wherein the refractive index of the first SiNₓ layer is 2.45, the refractive index of the second SiNₓ layer is 2, and the refractive index of the SiNₓO_{y} layer is 1.6, wherein the thickness of the first SiNₓ layer is 43 nm, the thickness of the second SiNₓ layer is 36 nm, and the thickness of the SiNₓO_{y} layer is 60 nm.

11. The antireflection coating of claim 2, wherein the refractive index difference between the first and the second SiNₓ layer and/or between the second SiNₓ layer and the SiNₓO_{y} layer is at least 0.2.

12. The antireflection coating of claim 1, wherein at least one of the refractive index of the first SiNₓ layer is 2.25 to 2.6, the refractive index of the second SiNₓ layer is 1.9 to 2.15, the refractive index of the SiNₓO_{y} layer is 1.45 to 1.7, the thickness of the first SiNₓ layer is 20 nm to 55 nm, the thickness of the second SiNₓ layer is 10 nm to 50 nm, and the thickness of the SiNₓO_{y} layer is greater than or equal to 20 nm.

13. The antireflection coating of claim 2, wherein at least one of refractive index of the first SiNₓ layer is 2.1 to 2.8, the refractive index of the second SiNₓ layer is 1.8 to 2.3, the refractive index of the SiNₓO_{y} layer is 1.45 to 1.9, the thickness of the first SiNₓ layer is 10 nm to 70 nm, the thickness of the second SiNₓ layer is 5 nm to 60 nm, and the thickness of the SiNₓO_{y} layer is greater than or equal to 20 nm.

14. The antireflection coating of claim 2, wherein that between the first and the second SiNₓ layer is provided a third SiNₓ layer, whose refractive index has the form of a gradient, wherein the largest refractive index is smaller than or equal the refractive index of the first SiNₓ layer and the smallest refractive index is larger than or equal the refractive index of the second SiNₓ layer.

15. The antireflection coating of claim 3, wherein that between the first and the second SiNₓ layer is provided a third SiNₓ layer, whose refractive index has the form of a gradient, wherein the largest refractive index is smaller than or equal the refractive index of the first SiNₓ layer and the smallest refractive index is larger than or equal the refractive index of the second SiNₓ layer.

16. The antireflection coating of claim 4, wherein that between the first and the second SiNₓ layer is provided a third SiNₓ layer, whose refractive index has the form of a gradient, wherein the largest refractive index is smaller than or equal the refractive index of the first SiNₓ layer and the smallest refractive index is larger than or equal the refractive index of the second SiNₓ layer.
